(19) United States
(12) Patent Application Publication
(10) Pub. No.: US 2026/0017020 A1
(43) Pub. Date: Jan. 15, 2026

(54) POWER-EFFICIENT MIXED-SIGNAL CIRCUIT INCLUDING ANALOG MULTIPLY AND ACCUMULATE ENGINES

(71) Applicant: INTERNATIONAL BUSINESS MACHINES CORPORATION, ARMONK, NY (US)

(72) Inventors: Andrea Fasoli, San Jose, CA (US); Ankur Agrawal, Chappaqua, NY (US); Monodeep Kar, New York, NY (US); Kyu-hyoun Kim, Chappaqua, NY (US); Sergey Rylov, White Plains, NY (US)

(21) Appl. No.: 18/772,079

(22) Filed: Jul. 12, 2024

(51) Int. Cl. G06F 7/544; H03K 19/20; H03M 1/12

(52) U.S. Cl. CPC G06F 7/5443; H03K 19/20; H03M 1/123

(57) ABSTRACT

A first integer value is split into a first coarse value and a first fine value, and a second integer value is split into a second coarse value and a second fine value. An analog multiply and accumulate (MAC) operation is performed on the first and second coarse values to produce a first analog output signal, an analog MAC operation is performed on the first coarse value and the second fine value to produce a second analog output signal, an analog MAC operation is performed on the first fine value and the second coarse value to produce a third analog output signal, and an analog MAC operation is performed on the first and second fine values to produce a fourth analog output signal. The first, second, third and fourth analog output signals are converted to first, second, third and fourth digital signals by first, second, third and fourth channels, respectively.

### BACKGROUND

### Technical Field

The present disclosure generally relates to circuits for performing matrix multiplication, and more particularly, to mixed-signal circuits that include analog multiply and accumulate units for performing matrix multiplication.

### Description of the Related Art

Matrix multiplication is performed in many machine learning algorithms, including neural networks. Matrix multiplication is also performed for graphics processing, scientific computations, Internet searching, etc.

Matrix multiplication may be performed in the digital domain by parallel processing units, or it may be performed in the analog domain by multiply and accumulate (MAC) units. MAC units based on switched capacitors offer greater power efficiency than digital processing units. Greater power efficiency is desirable for certain devices, such as edge computing devices at edges of distributed networks.

### SUMMARY

According to various embodiments, a system includes first, second and third circuits. The first circuit is configured to split a first integer value into a first coarse value and a first fine value, and split a second integer value into a second coarse value and a second fine value. The second circuit is configured to perform a MAC operation on the first and second coarse values to produce a first analog output signal, perform an analog MAC operation on the first coarse value and the second fine value to produce a second analog output signal, perform an analog MAC operation on the first fine value and the second coarse value to produce a third analog output signal, and perform an analog MAC operation on the first and second fine values to produce a fourth analog output signal. The third circuit includes first, second, third and fourth channels configured to convert the first, second, third and fourth analog output signals to first, second, third and fourth digital signals, respectively. The conversion of each analog output signal includes customized most significant bit (MSB) skipping and least significant bit (LSB) truncation such that each of the channels is configured to skip its own number of most significant bits and truncate its own number of least significant bits.

In some embodiments, the second circuit includes a first MAC engine configured to produce the first analog output signal, a second MAC engine configured to produce the second analog output signal, a third MAC engine configured to produce the third analog output signal, and a fourth MAC engine configured to produce the fourth analog output signal.

In some embodiments, the first, second, third and fourth MAC engines are switched capacitor-based.

In some embodiments, each channel includes a variable gain amplifier configured to perform customized MSB skipping followed by an analog-to-digital converter (ADC) configured to perform analog-to-digital (A/D) conversion and customized LSB truncation. The amplifier of each channel is configured to increase signal amplitude beyond full-scale input ranges of the A/D conversion.

In some embodiments, the third circuit further includes a controller for providing a customized gain to each amplifier of the first, second, third and fourth channels and for providing a customized truncation command to each ADC of the first, second, third and fourth channels.

In some embodiments, the ADCs of the first, second, third and fourth channels have the same precision. Total bit reduction equals m+k, where m represents a number of most significant bits skipped and k represents a number of least significant bits truncated, and where m and k are variable for each of the channels. Each of the channels performs the same total bit reduction.

In some embodiments, the ADCs do not all have the same precision. Total bit reduction for the i^{th} channel is N−pᵢ, where i={1,2,3,4}, N is a number of bits used to represent the i^{th} analog output signal, and pᵢ is precision of the ADC of the i^{th} channel. N−pᵢ=mᵢ+kᵢ, where mᵢ is a number of most significant bits skipped by the i^{th} channel and kᵢ is a number of least significant bits truncated by the i^{th} channel, and where mᵢ and kᵢ are variable for each channel.

In some embodiments, the controller is configured to adjust the customized gains of the amplifiers in real time. Adjusting the customized gain of each amplifier includes taking a sum of a second most significant bit over a number of A/D conversions, reducing the gain if the sum indicates that use of full amplifier range is above a threshold, and increasing the gain if the sum indicates that use of the full amplifier range is below a threshold.

In some embodiments, the first circuit is configured to receive a first vector having M integer values and a second vector having M integer values, where integer M>1 and where the first vector includes the first integer value and additional integer values, and the second vector includes the second integer value and additional integer values. The first circuit is further configured to split the first vector into a first coarse value vector and a first fine value vector, and split the second vector into a second coarse value vector and a second fine value vector. The second circuit is configured to generate the first analog output signal as a dot product of the first and second coarse value vectors, the second analog output signal as a dot product of the first coarse value vector and the second fine value vector, the third analog output signal as a dot product of the first fine value vector and the second coarse value vector, and the fourth analog output signal as a dot product of the first and second fine value vectors. The third circuit is configured to perform the customized MSB skipping and LSB truncation on the analog output signals after M accumulations have been completed.

In some embodiments, the integer values of first and second vectors are N bits wide, the integer values of the coarse value vectors are K bits wide, and the integer values of the fine value vectors are Y bits wide, where Y<N, K<N, and N, K and Y are integers.

In some embodiments, N=8, K=4 and Y=4. Each fine value has a rounded LSB. The system further includes a fourth circuit configured to produce a reconstructed digital output signal as

$${Y}_{R} = {2}^{8} Z 0 + {2}^{5} Z 1 + {2}^{5} Z 2 + {2}^{2} Z 3$$

where Y_{R} is the reconstructed digital output signal, and Z0, Z1, Z2 and Z3 are the first, second, third and fourth digital signals, respectively.

In some embodiments, N=8, K=4 and Y=5. The system further includes a fourth circuit configured to produce a reconstructed digital output signal as

$${Y}_{R} = {2}^{8} Z 0 + {2}^{4} Z 1 + {2}^{4} Z 2 + Z 3$$

where Y_{R} is the reconstructed digital output signal, and Z0, Z1, Z2 and Z3 are the first, second, third and fourth digital signals, respectively.

According to various embodiments, there is a computer-implemented method of multiplying first and second input vectors. Each of the input vectors has M integer values. The method includes splitting the first input vector into a first coarse value vector and a first fine value vector, and splitting the second input vector into a second coarse value vector and a second fine value vector. The method further includes using a plurality of MAC units to generate a first analog signal representing a dot product of the first and second coarse value vectors, a second analog signal representing a dot product of the first coarse value vector and the second fine value vector, a third analog signal representing a dot product of the first fine value vector and the second coarse value vector, and a fourth analog signal representing a dot product of the first and second fine value vectors. The method further includes performing amplification and A/D conversion on the first, second, third and fourth analog signals such that each amplification and A/D conversion skips its own number of most significant bits and truncates its own number of least significant bits.

According to various embodiments, a computing device for running a neural network includes a plurality of switched capacitor units configured to perform matrix multiplication on an input vector and a weight vector, and a digital processor programmed to apply activation functions to outputs of the switched capacitor units. Each switched capacitor unit is configured to split values of an input vector into first coarse value vectors and first fine value vectors, and split values of a weight vector into second coarse value vectors and second fine value vectors. Each switched capacitor unit is further configured to perform MAC operations to take a first dot product of the first and second coarse value vectors, a second dot product of the first coarse value vector and the second fine value vector, a third dot product of the first fine value vector and the second coarse value vector, and a fourth dot product of the first and second fine value vectors. Each switched capacitor unit is further configured to produce a reconstructed digital signal from the first, second, third and fourth dot products, including performing amplification and analog-to-digital (A/D) conversion on each dot product such that each amplification and A/D conversion skips its own number of most significant bits and truncates its own number of least significant bits.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is a mixed signal circuit, consistent with an illustrative embodiment.

FIG. 2 illustrates first and second INT8 values represented as coarse INT4 values and fine INT4 values, consistent with an illustrative embodiment.

FIG. 3 illustrates a signal before and after MSB skipping, consistent with an illustrative embodiment.

FIG. 4 is a method of reconstructing a digital output signal at full precision, consistent with an illustrative embodiment.

FIG. 5 is a method of reconstructing a digital output signal at less than full precision, consistent with an illustrative embodiment.

FIG. 6 is a method of determining a priori values of numbers of most significant bits to skip and least significant bits to truncate, consistent with an illustrative embodiment.

FIG. 7 is a method of determining a priori values of numbers of most significant bits to skip and least significant bits to truncate, consistent with an illustrative embodiment.

FIG. 8 is a method of performing real-time adjustment of values of numbers of most significant bits to skip and least significant bits to truncate, consistent with an illustrative embodiment.

FIG. 9 is a method of using the mixed signal circuit of FIG. 1, consistent with an illustrative embodiment.

FIG. 10 illustrates first and second INT8 values represented as coarse INT4 values and fine INT5 values, consistent with an illustrative embodiment.

FIG. 11 is a MAC processor based on switched capacitors, consistent with an illustrative embodiment.

FIG. 12 is a computing system, consistent with an illustrative embodiment.

FIG. 13 compares accuracy of full precision processing to processing with customized MSB skipping and LSB truncation and reduced precision ADCs.

### DETAILED DESCRIPTION

### Overview

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

The present disclosure generally relates to mixed signal circuits including analog multiply and accumulate engines. By virtue of the concepts discussed herein, power efficiency of the mixed signal circuits is increased and accuracy is preserved.

### Counterparting

According to an embodiment of the present disclosure, a system includes first, second and third circuits. The first circuit is configured to split a first integer value into a first coarse value and a first fine value, and split a second integer value into a second coarse value and a second fine value. The second circuit is configured to perform an analog multiply and accumulate (MAC) operation on the first and second coarse values to produce a first analog output signal, perform an analog MAC operation on the first coarse value and the second fine value to produce a second analog output signal, perform an analog MAC operation on the first fine value and the second coarse value to produce a third analog output signal, and perform an analog MAC operation on the first and second fine values to produce a fourth analog output signal. The third circuit includes first, second, third and fourth channels configured to convert the first, second, third and fourth analog output signals to first, second, third and fourth digital signals, respectively. The conversion of each analog output signal includes customized most significant bit (MSB) skipping and least significant bit (LSB) truncation such that each of the channels is configured to skip its own number of most significant bits and truncate its own number of least significant bits.

Analog MAC engines in general are more power-efficient at performing vector multiplication than digital processors. However, some (if not all) of that efficiency gain is lost during A/D conversion. The system enables vector multiplications to preserve some of that efficiency gain during A/D conversion. The customized MSB skipping and the LSB truncation enables the system to preserve accuracy of the digital output signal with reduced precision ADCs.

In some embodiments, which can be combined with the preceding embodiment, the second circuit includes a first MAC engine configured to produce the first analog output signal, a second MAC engine configured to produce the second analog output signal, a third MAC engine configured to produce the third analog output signal, and a fourth MAC engine configured to produce the fourth analog output signal.

In some embodiments, which can be combined with one or more preceding embodiments, the first, second, third and fourth MAC engines are switched capacitor-based.

In some embodiments, which can be combined with one or more preceding embodiments, each channel includes a variable gain amplifier configured to perform customized MSB skipping followed by an analog-to-digital converter (ADC) configured to perform analog-to-digital (A/D) conversion and customized LSB truncation. The amplifier of each channel is configured to increase signal amplitude beyond full-scale input ranges of the A/D conversion.

In some embodiments, which can be combined with one or more preceding embodiments, the third circuit further includes a controller for providing a customized gain to each amplifier of the first, second, third and fourth channels and for providing a customized truncation command to each ADC of the first, second, third and fourth channels.

In some embodiments, which can be combined with one or more preceding embodiments, total bit reduction equals m+k, where m represents a number of most significant bits skipped and k represents a number of least significant bits truncated, and where m and k are variable for each of the channels. Each of the channels performs the same total bit reduction. The ADCs of the first, second, third and fourth channels have the same precision.

In some embodiments, which can be combined with one or more preceding embodiments, m and k for each channel are determined a priori. The controller is configured to provide the customized gains and truncation commands based on k and m for each channel.

In some embodiments, which can be combined with one or more preceding embodiments, the ADCs do not all have the same precision. Total bit reduction for the i^{th} channel is N−pᵢ, where i={1,2,3,4}, N is a number of bits used to represent the i^{th} analog output signal, and pᵢ is precision of the ADC of the i^{th} channel. The total bit reduction N−pᵢ=mᵢ+kᵢ, where mᵢ is a number of most significant bits skipped by the i^{th} channel and kᵢ is a number of least significant bits truncated by the i^{th} channel, and where mᵢ and kᵢ are variable for each channel. By further reducing the precision of one or more ADCs, power efficiency may be improved even further, while accuracy is still preserved.

In some embodiments, which can be combined with one or more preceding embodiments, mᵢ and kᵢ are determined a priori. The controller is configured to provide the customized gains and truncation commands based on kᵢ and mᵢ.

In some embodiments, which can be combined with one or more preceding embodiments, the controller is configured to adjust the customized gains of the amplifiers in real time. Adjusting the customized gain of each amplifier includes taking a sum of a second most significant bit over a number of A/D conversions, reducing the gain if the sum indicates that use of full amplifier range is above a threshold, and increasing the gain if the sum indicates that use of the full amplifier range is below a threshold. Better use of the full amplifier range can further improve accuracy.

In some embodiments, which can be combined with one or more preceding embodiments, the first circuit is configured to receive a first vector having M integer values and a second vector having M integer values, where integer M>1 and where the first vector includes the first integer value and additional integer values, and the second vector includes the second integer value and additional integer values. The first circuit is further configured to split the first vector into a first coarse value vector and a first fine value vector, and split the second vector into a second coarse value vector and a second fine value vector. The second circuit is configured to generate the first analog output signal as a dot product of the first and second coarse value vectors, the second analog output signal as a dot product of the first coarse value vector and the second fine value vector, the third analog output signal as a dot product of the first fine value vector and the second coarse value vector, and the fourth analog output signal as a dot product of the first and second fine value vectors. The third circuit is configured to perform the customized MSB skipping and LSB truncation on the analog output signals after M accumulations have been completed.

In some embodiments, which can be combined with one or more preceding embodiments, the A/D conversions are then performed at less than full precision after the M accumulations have been completed, where full precision is defined as 2X+log 2(M), where N is bit width of the first and second integer values.

The system has a flexible architecture. In some embodiments, which can be combined with the preceding embodiments, the integer values of first and second vectors are N bits wide, the integer values of the coarse value vectors are K bits wide, and the integer values of the fine value vectors are Y bits wide, where Y<N, K<N, and N, K and Y are integers.

In some embodiments, which can be combined with one or more preceding embodiments, N=8, K=4 and Y=4. Each fine value has a rounded LSB. The system further includes a fourth circuit configured to produce a reconstructed digital output signal as

$${Y}_{R} = {2}^{8} Z 0 + {2}^{5} Z 1 + {2}^{5} Z 2 + {2}^{2} Z 3$$

where Y_{R} is the reconstructed digital output signal, and Z0, Z1, Z2 and Z3 are the first, second, third and fourth digital signals, respectively.

In some embodiments, which can be combined with one or more preceding embodiments, N=8, K=4 and Y=5. The system further includes a fourth circuit configured to produce a reconstructed digital output signal as

$${Y}_{R} = {2}^{8} Z 0 + {2}^{4} Z 1 + {2}^{4} Z 2 + Z 3$$

where Y_{R} is the reconstructed digital output signal, and Z0, Z1, Z2 and Z3 are the first, second, third and fourth digital signals, respectively.

According to an embodiment of the present disclosure, there is a computer-implemented method of multiplying first and second input vectors. Each of the input vectors has M integer values. The method includes splitting the first input vector into a first coarse value vector and a first fine value vector, and splitting the second input vector into a second coarse value vector and a second fine value vector. The method further includes using a plurality of MAC units to generate a first analog signal representing a dot product of the first and second coarse value vectors, a second analog signal representing a dot product of the first coarse value vector and the second fine value vector, a third analog signal representing a dot product of the first fine value vector and the second coarse value vector, and a fourth analog signal representing a dot product of the first and second fine value vectors. The method further includes performing amplification and A/D conversion on the first, second, third and fourth analog signals such that each amplification and A/D conversion skips its own number of most significant bits and truncates its own number of least significant bits.

In some embodiments of the method, which can be combined with the preceding embodiment, the amplification includes increasing signal amplitude beyond full-scale input range of the A/D conversion.

In some embodiments of the method, which can be combined with one or more preceding embodiments, the method further includes producing a reconstructed digital output signal from first, second, third and fourth digital output signals produced by the A/D conversion, such that the reconstructed digital output signal represents a dot product of the first and second input vectors.

The improvement in power efficiency is especially valuable for edge computing devices at the edges of a distributed system. Applications performed by such devices include, but are not limited to, neural networks and other machine learning models, graphics, scientific computation, and Internet searching.

According to an embodiment of the present disclosure, a computing device for running a neural network includes a plurality of switched capacitor units configured to perform matrix multiplication on an input vector and a weight vector, and a digital processor programmed to apply activation functions to outputs of the switched capacitor units. Each switched capacitor unit is configured to split values of an input vector into first coarse value vectors and first fine value vectors, and split values of a weight vector into second coarse value vectors and second fine value vectors. Each switched capacitor unit is further configured to perform MAC operations to take a first dot product of the first and second coarse value vectors, a second dot product of the first coarse value vector and the second fine value vector, a third dot product of the first fine value vector and the second coarse value vector, and a fourth dot product of the first and second fine value vectors. Each switched capacitor unit is further configured to produce a reconstructed digital signal from the first, second, third and fourth dot products, including performing amplification and analog-to-digital (A/D) conversion on each dot product such that each amplification and A/D conversion skips its own number of most significant bits and truncates its own number of least significant bits.

In some embodiments of the device, which can be combined with the preceding embodiment, each switched capacitor unit includes first, second, third and fourth switched capacitor-based MAC engines configured to produce the first, second, third and fourth dot products, respectively.

### Example Construction

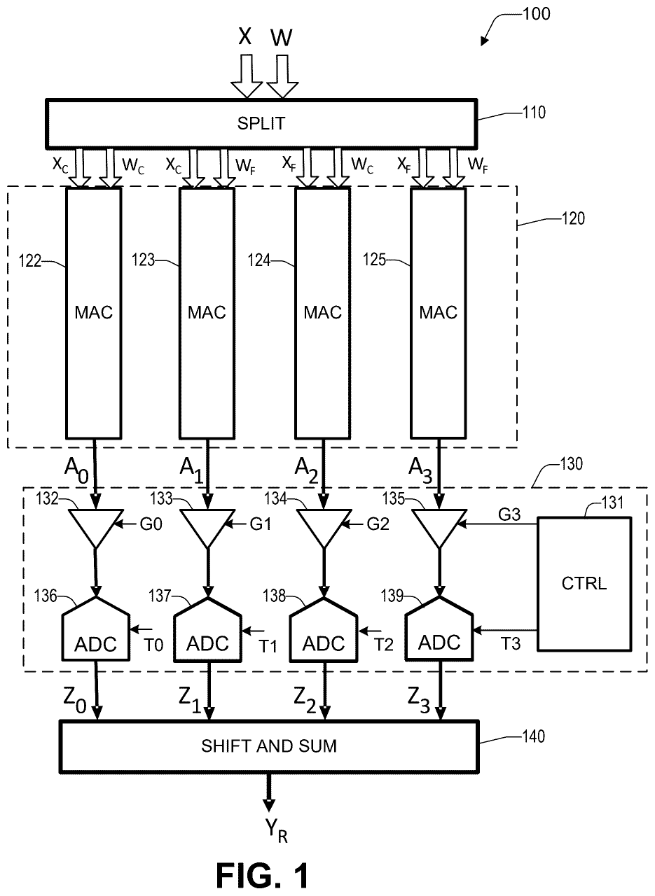

Reference is made to FIG. 1, which illustrates a mixed signal circuit 100 for performing a vector multiplication on first and second vectors X and W. Each vector X and W is an M×N vector, where integer M represents the number of words, and N represents the number of bits per word. Thus, X={x₁, . . . x_{M}} and W={w₁, . . . w_{M}}. Initially, the circuit 100 will be described for a 1×N vector, where the vector X includes a first N-bit integer value (x1), and the vector W includes a second N-bit integer value (w1).

The mixed signal circuit 100 includes first, second, third and fourth circuits 110, 120, 130 and 140. The first circuit 110 is configured to split the first integer value x1 into a first coarse value x_{C} and a first fine value x_{F}, and split the second integer value w1 into a second coarse value w_{C} and a second fine value w_{F}. The first circuit 110 may include basic logic gates (e.g., NAND gates) for performing the splitting.

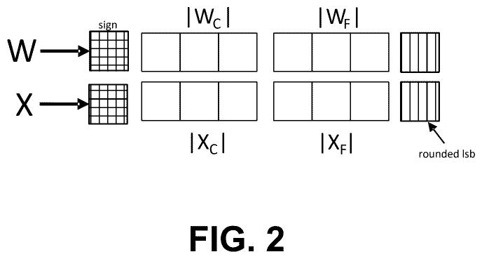

Additional reference is made to FIG. 2, which shows an example of splitting INT8 values into coarse INT4 value and fine INT4 values. INT8 is an 8-bit signed integer having a sign bit and seven magnitude bits. The first circuit 110 splits the first integer value x1 into a 4-bit first coarse value x_{C} and a 4-bit first fine value X_{F}. The first circuit 110 also splits the second integer w1 into a 4-bit second coarse value w_{C} and a 4-bit second fine value w_{F}. Each coarse value x_{C} and w_{C} has a sign bit and three bits magnitude. Each fine value x_{F} and w_{F} has a sign bit and three bits magnitude. The least significant bit (LSB) is rounded. Different rounding strategies include, but are not limited to, nearest neighbor, truncation, and stochastic rounding.

The coarse values x_{C} and w_{C} and the fine values x_{F} and w_{F} may be represented as follows:

$$Xc = sign ( X ) * Trunc ( \frac{\vert X \vert}{{2}^{4}} )$$

$${X}_{F} = sign ( X ) * Trunc ( Remainder \frac{( \vert X \vert , {2}^{4} )}{2} )$$

$$Wc = sign ( W ) * Trunc ( \frac{\vert W \vert}{{2}^{4}} )$$

$${W}_{F} = sign ( W ) * Trunc ( Remainder \frac{( \vert W \vert , {2}^{4} )}{2} )$$

Thus, the first and second integer values x1 and w1 may be approximated as:

$$x 1 ≅ {2}^{4} {X}_{C} + 2 {X}_{F}$$

$$w 1 ≅ {2}^{4} {W}_{C} + 2 {W}_{F}$$

These are approximations of integer values x1 and w1 because the rounding of the LSB may introduce some error.

Returning to FIG. 1, the second circuit 120 includes a first analog multiply and accumulate (MAC) engine 122 for performing a MAC operation on the first and second coarse values x_{C} and w_{C} to produce a first analog output signal A0, a second MAC engine 123 for performing an analog MAC operation on the first coarse value x_{C} and the second fine value wp to produce a second analog output signal A1, a third MAC engine 124 for performing an analog MAC operation on the first fine value x_{F} and the second coarse value w_{C} to produce a third analog output signal A2, and a fourth MAC engine 125 for performing an analog MAC operation on the first and second fine values x_{F} and w_{F} to produce a fourth analog output A3. Thus,

$$A 0 = {x}_{C} {w}_{C ,} , A 1 = {x}_{C} {w}_{F} , A 2 = {x}_{F} {w}_{C} , and A 3 = {x}_{F} {w}_{F} .$$

The third circuit 130 is configured to convert the analog output signals A0, A1, A2 and A3 to first, second, third and fourth digital output signals Z0, Z1, Z2 and Z3, respectively. The conversion of each analog output signal A0, A1, A2 and A3 includes customized most significant bit (MSB) skipping and least significant bit (LSB) truncation.

In the embodiment illustrated in FIG. 1, a first channel includes a first variable gain amplifier 132 and a first A/D converter 136 for converting the first analog output signal A0 to the first digital output signal Z0. A second channel includes a second variable gain amplifier 133 and a second A/D converter 137 for converting the second analog output signal A1 to the second digital output signal Z1. A third channel includes a third variable gain amplifier 134 and a third A/D converter 138 for converting the third analog output signal A2 to the third digital output signal Z2. A fourth channel includes a fourth variable gain amplifier 135 and a fourth A/D converter 139 for converting the fourth analog output signal A3 to the fourth digital output signal Z3.

The MSB skipping may be performed by the amplifiers 132, 133, 134 and 135, which are configured to increase the signal amplitude of the analog output signals A0, A1, A2, and A3 beyond full-scale input range of the A/D converters 136, 137, 138 and 139. As for LSB truncation, the A/D converters 136, 137, 138 and 139 may be commanded to truncate a desired number of least significant bits.

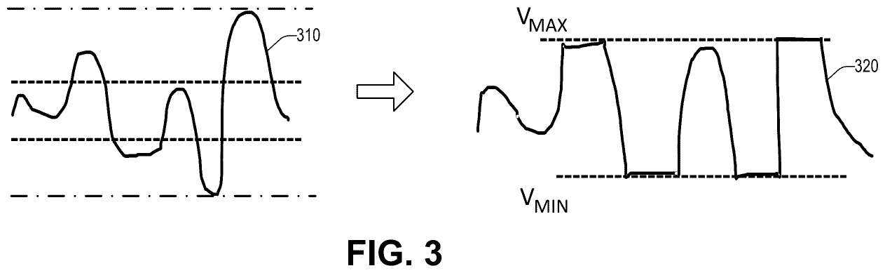

Additional reference is made to FIG. 3, which illustrates an example of an analog signal 310 before and after MSB skipping. The dot-dash lines indicate the full dynamic range of the analog signal 310. The dash lines indicate full scale input range of A/D conversion. Because the dynamic range of the analog signal 310 is beyond the full scale input range of A/D conversion, those portions of the analog signal 310 are saturated to V_{MAX} and V_{MIN}, whereby A/D conversion is performed on a clipped analog signal 320.

The MSB skipping and LSB truncation are customized. As used herein, the term “customized MSB skipping” refers to each of the channels being configured to skip its own number of most significant bits, as opposed to all of the channels being configured to skip the same number of most significant bits. As used herein the term “customized LSB truncation” refers to each of the channels being configured to truncate its own number of least significant bits, as opposed to all of the channels being configured to truncate the same number of least significant bits. As used herein, the term “customized MSB skipping and LSB truncation” refers to customized MSB skipping and customized LSB truncation.

The third circuit 130 further includes a controller 131 for controlling the amplifiers 132, 133, 134 and 135 to perform customized MSB skipping, and the A/D converters 136, 137, 138 and 139 to perform customized LSB truncation. For example, the controller 131 may provide customized gains G0, G1, G2, and G3 to the amplifiers 132, 133, 134 and 135, respectively, and it may provide customized truncation commands T0, T1, T2 and T3 to the A/D converters 136, 137, 138 and 139, respectively.

The fourth circuit 140 is configured to combine the converted output signals Z0, Z1, Z2 and Z3 into a reconstructed digital output signal Y_{R}. For example, the digital signal Z0 is shifted by eight bits, the digital signal Z1 is shifted by five bits, the digital signal Z2 is shifted by five bits, and the digital signal Z3 is shifted by two bits. These shifted digital signals 2⁸Z0, 2⁵Z1, 2⁵Z2 and 2²Z3 are summed to produce a reconstructed digital output Y_{R}. Thus,

$${Y}_{R} = {2}^{8} Z 0 + {2}^{5} Z 1 + {2}^{5} Z 2 + {2}^{2} Z 3.$$

The fourth circuit 140 may be implemented with shift registers and adders.

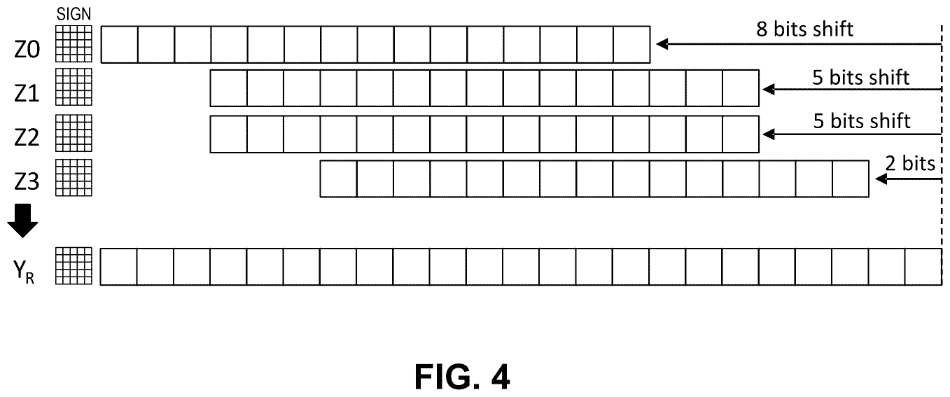

Reference is made to FIG. 4, which illustrates a reconstructed digital output signal Y_{R} where the A/D conversion is performed at full precision, without MSB skipping or LSB truncation. Each of the digital output signals Z0, Z1, Z2 and Z3 at full precision A/D conversion has 2N+log (M) magnitude bits and one sign bit. For example, if each MAC engine 122, 123, 124 and 125 performs M=2⁹ accumulations, and each of the digital values Z0, Z1, Z2 and Z3 has a sign bit and 3 magnitude bits, then each of the digital values Z0, Z1, Z2 and Z3 at full precision has 2 (3)+9=15 magnitude bits and one sign bit. The reconstructed signal Y_{R} has 23 magnitude bits and one sign bit. This is the same number of bits as the product of two INT8 vectors without the splitting.

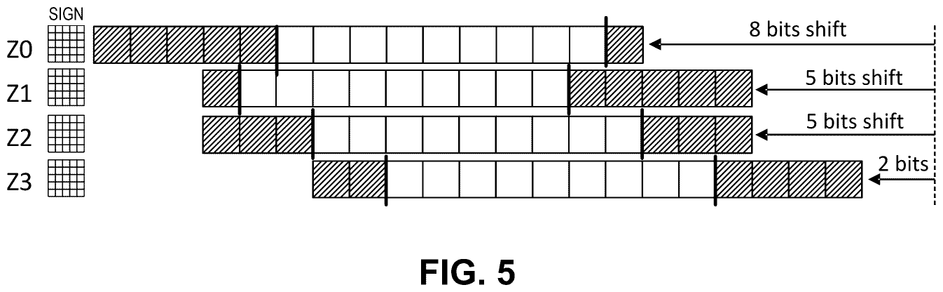

Reference is made to FIG. 5, which illustrates a reconstructed signal Y_{R} where the third circuit 130 performs the A/D conversion at less than full precision with customized MSB skipping in the amplifiers 132, 133, 134 and 135 and LSB truncation in the A/D converters 136, 137, 138 and 139. In the example of FIG. 5, the first digital output signal Z0 has five most significant magnitude bits skipped and one least significant magnitude bit truncated. The second digital output signal Z1 has one most significant magnitude bit skipped and five least significant magnitude bits truncated. The third digital output signal Z2 has three most significant magnitude bits skipped and three least significant magnitude bits truncated. The fourth digital output signal Z3 has two most significant magnitude bits skipped and four least significant magnitude bits truncated.

The customized MSB skipping and the LSB truncation allow each A/D converter 136, 137, 138 and 139 to perform A/D converter on ten magnitude bits instead of fifteen magnitude bits. Resulting are substantially smaller A/D converters 136, 137, 138 and 139 that consume less power, while preserving accuracy. Lower power consumption is advantageous in terms of energy savings, thermal dissipation, and chip real estate.

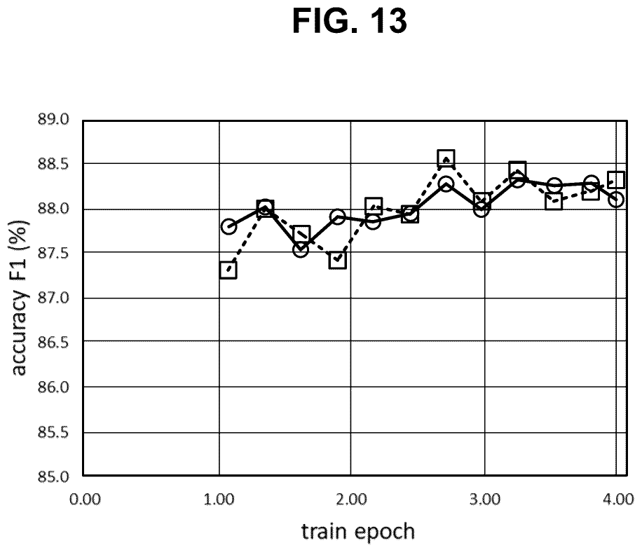

Reference is made to FIG. 13, which illustrates the preservation of accuracy in a simulation of a Bidirectional Encoder Representations from Transformers (BERT)-base network quantized at eight bits (INT8). A solid line represents processing with full precision ADCs, no MSB skipping and no LSB truncation. A dash line represents processing with customized MSB skipping and LSB truncation and reduced precision ADCs. The same accuracy is achieved (F1˜88.5%).

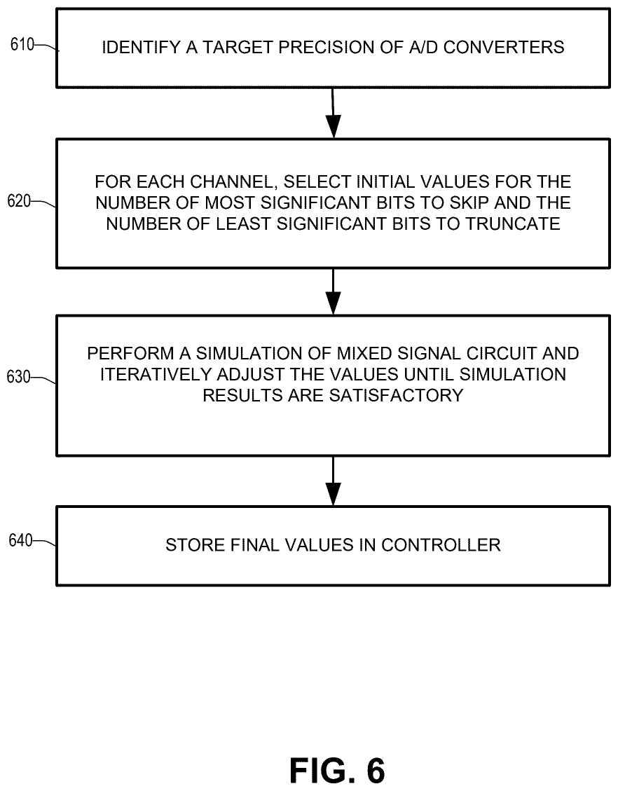

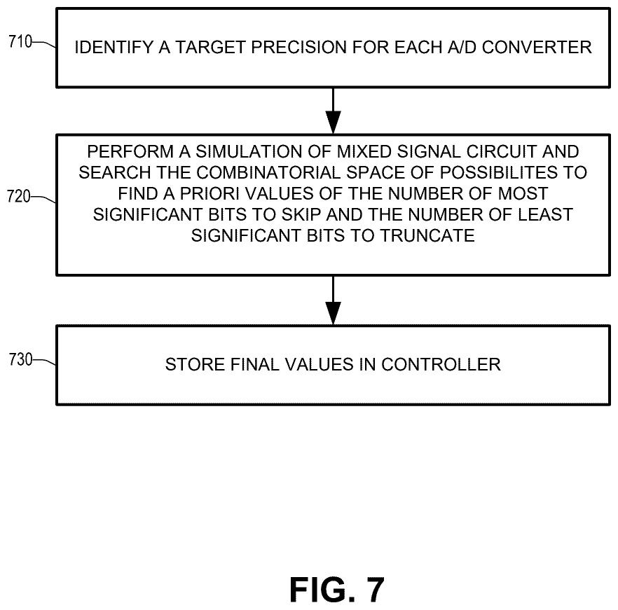

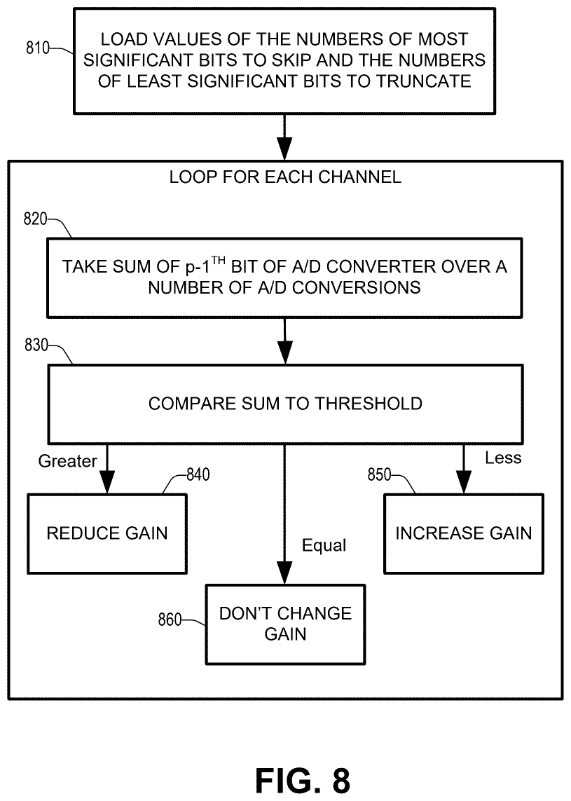

FIGS. 6, 7 and 8 illustrate three examples of determining the numbers of bits to skip and truncate for each channel. In the examples of FIGS. 6 and 7, the numbers of bits skipped and truncated for each channel are determined a priori. In the example of FIG. 8, the numbers of bits skipped and truncated for each channel are determined in real time.

Reference is made to FIG. 6. In this first example, the A/D converters 136, 137, 138 and 139 have the same precision. For example, let i={0, 1, 2, 3}, let p represent the number of bits of A/D converter precision, let Q represent the number of bits to represent an output of each MAC engine 122, 123, 124 and 125 in full precision, let mᵢ represent the number of most significant bits skipped in the i^{th} channel, and let kᵢ represent the number of least significant bits truncated in the i^{th} channel.

At block 610, a target precision is identified. Let the target precision be defined as (Q−p). The target precision represents the total number of bits skipped and truncated during the conversion of each analog output signal A0, A1, A2 and A3. The total bit reduction by each of the channels is the same. Thus, (Q−p)=(m₀+k₀)=(m₁+k₁)=(m₂+k₂)=(m₃+k₃). However, mᵢ and kᵢ are customized for each of the channels. See FIG. 5, for example. Each of the digital output signals Z0, Z1, Z2 and Z3 has a total bit reduction of 6 bits. However, mᵢ and kᵢ are different for each of the channels.

At blocks 620-630 a priori values of mᵢ and kᵢ for each channel are determined. At block 620, initial value of mᵢ and kᵢ are selected. The initial values may be based on knowledge of expected value distributions of the digital output signals Z0, Z1, Z2 and Z3.

At block 630, performance of the mixed signal circuit 100 with the initial values is simulated in software, and a selected metric is monitored. Metrics such as accuracy, F1 score and loss are a few examples. The values of mᵢ and kᵢ are iteratively adjusted until simulation results are satisfactory.

At block 640, once the results of the simulation are satisfactory, final values of mᵢ and kᵢ are stored in the controller 131. The controller 131 sets the amplifier gains and truncation commands based on mᵢ and kᵢ.

Reference is made to FIG. 7. In this second example, the A/D converters 136, 137, 138 and 139 may have different precisions, and mᵢ and kᵢ are variable for each channel.

At block 710, a target precision is identified for each A/D converter 136, 137, 138 and 139. Let pᵢ represent the number of bits of precision in the A/D converter of the i^{th} channel. For each i in {0, 1, 2, 3}, let Q−pᵢ=(mᵢ+kᵢ).

At block 720, performance of the mixed signal circuit 100 is simulated in software. The combinatorial space of possibilities is searched to find a priori values. Define P as the set of unique pᵢ, and \tilde{p}ⱼ an element of \tilde{P}. For example, if P={8,8,9,9} with 2× 8-bit ADCs and 2×9-bit ADCs, then \tilde{P}={8,9} is the set of unique elements of P. The search may be expanded to include combinations over unique \tilde{p}ⱼ: 4^{Ø}^{ⱼ}^{(N-\tilde{p}}^{ⱼ}⁾.

At block 730, final values of mᵢ and kᵢ are stored in the controller 131.

Thus, the example of FIG. 7 may enable the precision of one or more ADCs to be reduced even further, while still preserving accuracy. Advantageously, power requirements may be reduced even further.

Reference is made to FIG. 8, which illustrates the example in which gains of the amplifiers 132, 133, 134 and 135 are adjusted in real time. At block 810, values for mᵢ and kᵢ are loaded into the controller 131. These values may be determined via the examples of FIG. 6 or FIG. 7.

Blocks 820 to 860 are performed in a loop for each channel. At block 820, the p−1^{th} bit of the A/D converter of the i^{th} channel is summed over a number Y of A/D conversions. At block 830, after Y A/D conversions have been performed, the resulting sum is compared to a threshold. The gain of the variable gain amplifier is reduced if the sum is greater than the threshold (block 840). The gain of the variable gain amplifier is increased if the sum is less than the threshold (block 850). If the sum is equal to the threshold, the gain is not changed (block 860).

The threshold may indicate that if the full range of the amplifier is not being used frequently enough, the gain is increased. Conversely, if the full range is not being used frequently, the gain is reduced.

Blocks 820 to 860 are repeated in a loop for each channel.

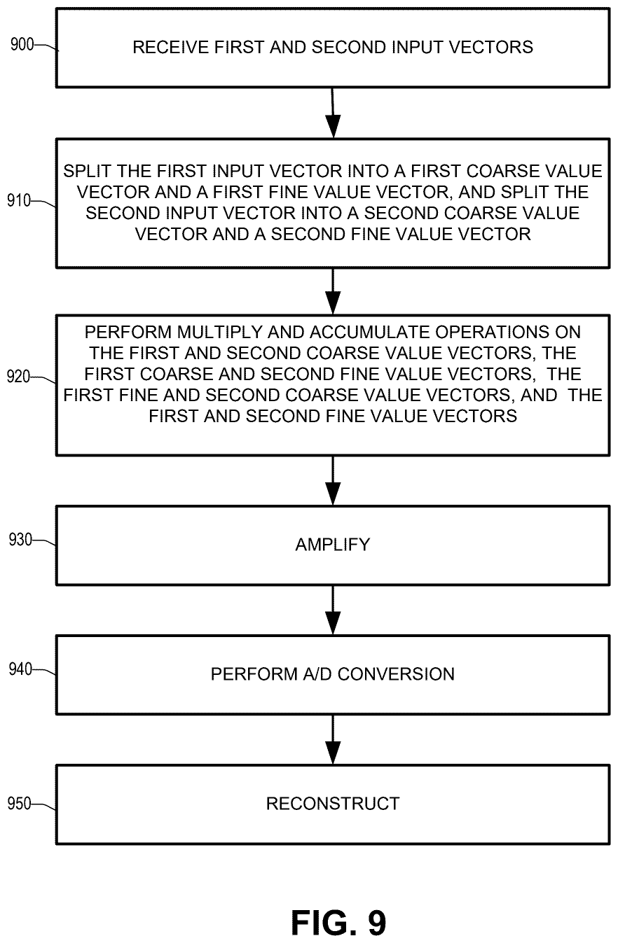

Reference is now made to FIG. 9 which illustrates a method of using the mixed signal circuit 100 of FIG. 1. In the method of FIG. 3, M>1.

At block 900, first and second input vectors X and W are received. Each input vector X, W is an M×N vector. For example, each input vector X, W has M=512 integer values and N=8 bits per value.

At block 910, the first circuit 110 is used to split the first input vector X into a first coarse value vector X_{C} and a first fine value vector X_{F}. The first circuit 110 is also used to split the second input vector W into a second coarse value vector W_{C} and a second fine value vector W_{F}.

The first coarse value vector X_{C} refers to a vector of the coarse values in X. Thus,

$${X}_{C =} \{ {x}_{c 1} , … , {x}_{c M} \} .$$

Similarly, the first fine value vector X_{F} refers to a vector of the fine values in X, the second coarse value vector W_{C} refers to a vector of the coarse values in W, and the second fine value vector X_{F} refers to a vector of the fine values in W. Thus

$${X}_{F =} \{ {x}_{f 1} , … , {x}_{fM} \}$$

$${W}_{C =} \{ {w}_{c 1} , … , {w}_{c M} \}$$

$${W}_{F =} \{ {w}_{f 1} , … , {w}_{fM} \} .$$

At block 920, the first MAC engine 122 is used to perform a multiply and accumulate operation on the first and second coarse value vectors X_{C} and W_{C}. The output analog signal A0 of the first MAC engine 122 represents a dot product of these two vectors X_{C} and W_{C}.

The second MAC engine 123 is used to perform a multiply and accumulate operation on the first coarse value vector and the second fine value vector X_{C} and W_{F}. The output analog signal A1 of the second MAC engine 122 represents a dot product of the of these two vectors X_{C} and W_{F}.

The third MAC engine 124 is used to perform a multiply and accumulate operation on the first fine value vector and the second coarse value vector X_{F} and W_{C}. The output analog signal A2 of the third MAC engine 124 represents a dot product of the of these two vectors X_{C} and W_{F}.

The fourth MAC engine 125 is used to perform a multiply and accumulate operation on the first and second fine value vectors X_{F} and W_{F}. The output analog signal A3 of the fourth MAC engine 125 represents a dot product of these two vectors X_{F} and W_{F}.

At the end of block 920, a total of M accumulations have been performed by each MAC engine 122, 123, 124 and 125.

At block 930, the amplifiers 132, 133, 134 and 135 operate on the analog output signals A0, A1, A2 and A3 outputted by the first, second, third, and fourth MAC engines 122, 123, 124 and 125. Customized gains G0, G1, G2, G3 and G4 for the amplifiers 132, 133, 134 and 135 are supplied by the controller 131.

At block 940, the A/D converters 136, 137, 138 and 139 perform A/D conversion on amplified analog output signals to produce first, second, third and fourth digital values Z0, Z1, Z2 and Z3. Customized truncation commands T0, T1, T2 and T3 for the A/D converters 136, 137, 138 and 139 are supplied by the controller 131.

At block 950, the first, second, third and fourth digital values Z0, Z1, Z2 and Z3 are shifted and linearly combined to produce a reconstructed digital output signal Y_{R}. The reconstructed digital output signal Y_{R} represents a dot product of the first and second input vectors X and W.

A mixed signal circuit herein is not limited to splitting N-bit integer values into coarse values having N/2 bits and fine values having N/2 bits. For example, the coarse values may be INT4 values, and the fine values may be INT5 values.

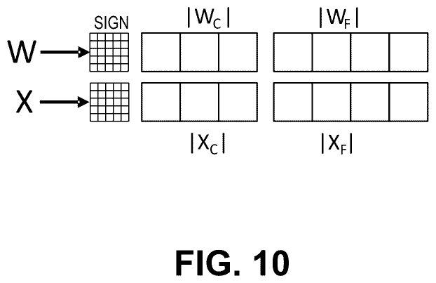

Reference is now made to FIG. 10, which shows an example of splitting vectors X and W of INT8 values into vectors X_{C} and W_{C} of coarse INT4 values and vectors X_{F} and W_{F} of fine INT5 values. Each j^{th} coarse value x_{Cj} and w_{Cj} has a sign bit and three magnitude bits. Each j^{th} fine value x_{Fj} and w_{Fj} has a sign bit and four magnitude bits. The LSB is not rounded. Values in the coarse value vectors X_{C} and W_{C} and the fine value vectors X_{F} and W_{F} may be represented as follows:

$$Xc = sign ( X ) * Trunc ( \frac{\vert X \vert}{{2}^{4}} )$$

$${X}_{F} = sign ( X ) * Remainder \frac{( \vert X \vert , {2}^{4} )}{2}$$

$$Wc = sign ( W ) * Trunc ( \frac{\vert W \vert}{{2}^{4}} )$$

$${W}_{F} = sign ( W ) * Trunc ( Remainder \frac{( \vert W \vert , {2}^{4} )}{2} )$$

After each MAC engine 122, 123, 124 and 125 has completed M accumulations, the outputs of the MAC engines 122, 123, 124 and 125 are amplified and A/D converted, and the resulting digital values Z0, Z1, Z2 and Z3 are shifted and combined as follows to produce the reconstructed output signal Y_{R}:

$${Y}_{R} = {2}^{8} Z 0 + {2}^{4} Z 1 + {2}^{4} Z 2 + Z 3 .$$

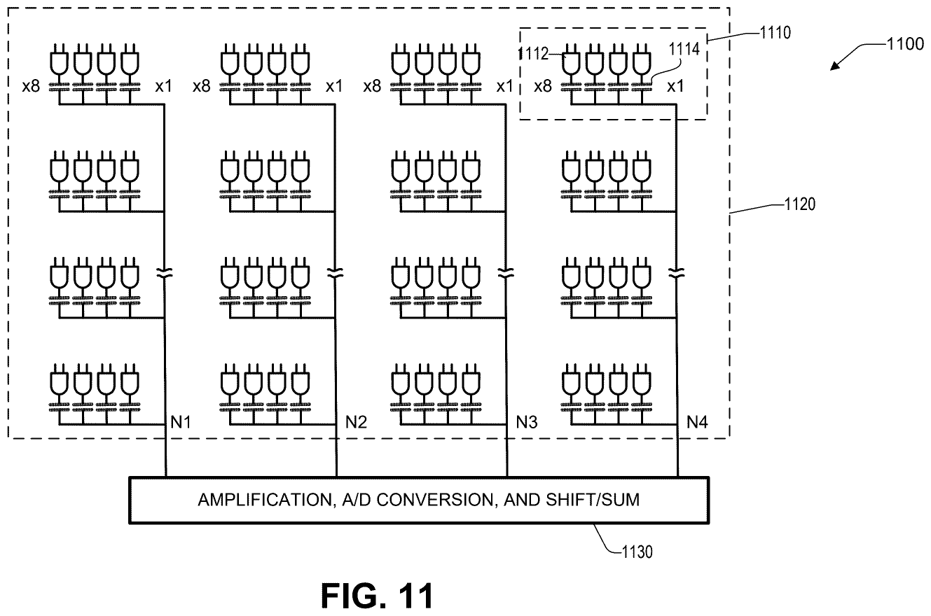

Reference is now made to FIG. 11, which illustrates an example of a MAC processor 1100 that is based on switched capacitors. The MAC processor 1100 includes a second circuit 1120 for performing MAC operations. The second circuit 1120 includes four columns of cells 1110. Each cell 1110 includes four AND gates 1112 and four capacitor units 1114 for performing a 4b×1b multiplication. The M rows correspond to M multiplies and accumulations. Each column performs M 4b×1b multiplication in parallel.

Each capacitor unit 1114 may include differential first and second capacitors. The differential capacitors can store a +1 unit of charge or −1 unit of charge.

Each column is configured for INT5 operations. The four AND gates 1112 and the four capacitor units 1114 correspond to the four magnitude bits. The notations “×8” and “×1” denote that a capacitor in the leftmost unit 1114 in a cell 1110 is eight times the size of a capacitor in the rightmost unit 1114. The capacitors in a cell are ×1, ×2, ×4 and ×8 (right to left). This done to implement a 4b×1b multiplication in the charge domain.

Consider an example in which vectors X and W are unsigned (for simplicity), and one input to each of the four AND gates 1112 in the cell 1110 of the rightmost column is X(0) bit and the other input is W(3), W(2), W(1) and W(0) respectively. Thus, the cell 1110 contributes charge equal to the 4b×1b product to the node N4. Going down the rightmost column, a total of M such terms are summed to perform an M-way MAC, and node N4 has charge corresponding to the 4b×1b×M way MAC. The corresponding cell to the left performs the same operation, except that inputs to the AND gates are now X(1) [shared] and W(3), W(2), W(1) and W(0). Node N3 thus develops charge corresponding to another 4b×1b×M way MAC.

Thus, accumulated charge at node N1 represents the dot product of the coarse value vectors. Accumulated charge at node N2 represents the dot product of the first coarse value vector and the second fine value vector. Accumulated charge at node N3 represents the dot product of the first fine value vector and the second coarse value vector. Accumulated charge at node N4 represents the dot product of the fine value vectors.

The MAC processor 1100 includes a third circuit 1130 for amplifying, converting and combining analog signals provided by the second circuit 1120. The third circuit 1130 may include amplifiers, analog-to-digital converters and shift and sum registers.

The example above assumes X(3:0) and W(3:0) are unsigned. For signed values, the circuits 1120 and 1130 would be modified to perform mathematically correct operations and the ability to sum+ve and −ve charge packets on the nodes N1, N2, N3 and N4.

Each A/D converter may be a successive approximation register (SAR) A/D converter. A SAR A/D converter converts an amplified analog signal into a discrete digital representation using a binary search through all possible quantization levels before finally converging upon a digital output for each conversion.

A mixed signal circuit herein can be configured to enable a choice between different levels of approximation. For example, the mixed signal circuit 100 of FIG. 1 can be modified to select additional modes of operation, such as a single INT8 MAC operation and a single INT4 operation (1×INT4). For these additional modes, circuitry may be added to configure how the first circuit 110 splits the input vectors, and the shift-and-sum circuit 140 may be modified so it can be bypassed.

The choice between different levels of approximation, in turn, enables the ability to select the most favorable set of output metrics (accuracy vs. energy efficiency vs. throughput vs. model size) to better fit the requirements of an application (e.g., a machine learning model). For instance, operating in 4×INT4 mode offers higher throughput (4× higher) but at worse overall workload accuracy. Operating in 4×INT4 mode also allows weights to be stored for a twice as large neural network trained model compared to INT8 mode. Thus, overall, lower precision computation not only improves energy efficiency directly (by simplifying computations), but also streamlines data movement costs.

Thus, in one aspect, disclosed are power-efficient mixed signal circuits that compute the dot product of two vectors, yet preserve accuracy. For systems that perform matrix multiplication-style computation on a large scale, where arrays of such circuits are used, the improvement in power efficiency is significant. The improvement in power efficiency is especially valuable for edge computing devices that run applications that include, but are not limited to, neural networks and other machine learning models, graphics, scientific computation, and Internet searching.

### Example Particularly Configured for Neural Networks

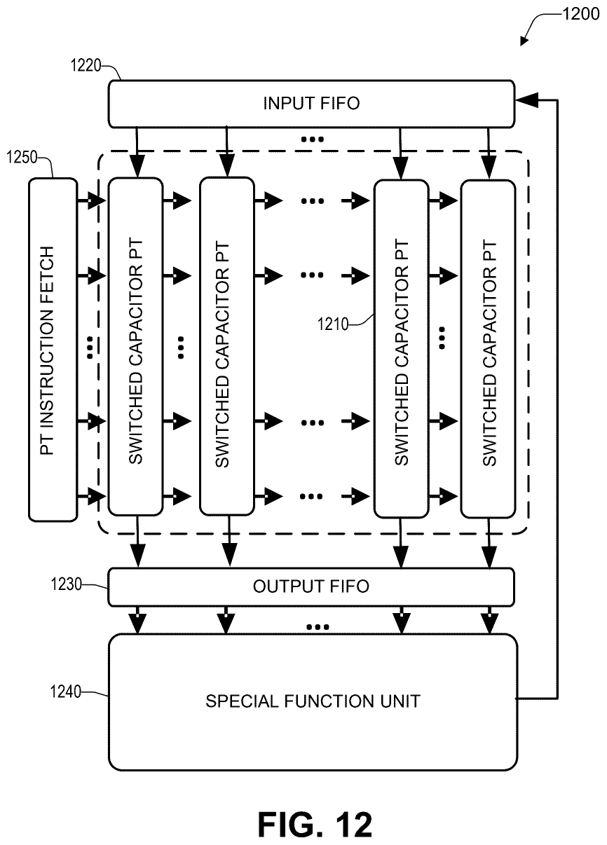

Reference is now made to FIG. 12, which illustrates certain elements of a computing system 1200 that implements a layer of a neural network. The system 1200 includes a plurality of processing tiles (PTs) 1210 based on switched capacitors. In some embodiments, each switched capacitor PT 1210 may include the MAC processor 1100 of FIG. 11 or other mixed signal circuit herein. Each switched capacitor PT 1210 receives two vectors—an input vector X and a vector W of weights—from an input FIFO buffer 1220, and performs splitting, vector multiplication, amplification, A/D conversion, and reconstruction of a digital output signal. The reconstructed digital output signal of each switched capacitor PT 1210 is sent to an output FIFO buffer 1230. A special function unit 1240 includes a digital processor that performs computations corresponding to batch normalization, activation functions (e.g., sigmoid functions, rectified linear unit functions) and SoftMax functions. Outputs of one layer are sent to the input FIFO buffer 1220 as an input vector for the next layer. A vector of weights for the next layer is also sent to the input FIFO buffer 1220 and stored in local storage such as register files (not shown) in each switched capacitor PT 1210, and another layer is processed.

Different PTs 1210 may have different values for the number of most significant bits to skip and the least significant bits to truncate. Moreover, with reference to a neural network, these different values may also be layer-dependent. That is, different neural network layers may be mapped to computing systems 1200 whose different PTs have different values for the numbers of most significant bits to skip and least significant bits to truncate.

A PT instruction fetch unit 1250 fetches and issues instructions to the switched capacitor PTs 1210 to control the operation of the switched capacitor PTs 1210, the input of the vectors, and the output of the reconstructed digital outputs.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A system comprising:
a first circuit configured to:
split a first integer value into a first coarse value and a first fine value; and
split a second integer value into a second coarse value and a second fine value;
a second circuit configured to:
perform an analog multiply and accumulate (MAC) operation on the first and second coarse values to produce a first analog output signal;
perform an analog MAC operation on the first coarse value and the second fine value to produce a second analog output signal;
perform an analog MAC operation on the first fine value and the second coarse value to produce a third analog output signal; and
perform an analog MAC operation on the first and second fine values to produce a fourth analog output signal; and
a third circuit comprising first, second, third and fourth channels configured to convert the first, second, third and fourth analog output signals to first, second, third and fourth digital signals, respectively;
wherein the conversion of each analog output signal includes customized most significant bit (MSB) skipping and least significant bit (LSB) truncation such that each of the channels is configured to skip its own number of most significant bits and truncate its own number of least significant bits.

2. The system of claim 1, wherein the second circuit comprises:
a first MAC engine configured to produce the first analog output signal;
a second MAC engine configured to produce the second analog output signal;
a third MAC engine configured to produce the third analog output signal; and
a fourth MAC engine configured to produce the fourth analog output signal.

3. The system of claim 2, wherein the first, second, third and fourth MAC engines are switched capacitor-based.

4. The system of claim 1, wherein:
each channel includes a variable gain amplifier configured to perform customized MSB skipping followed by an analog-to-digital converter (ADC) configured to perform analog-to-digital (A/D) conversion and customized LSB truncation, the amplifier configured to increase signal amplitude beyond full-scale input ranges of the A/D conversion.

5. The system of claim 4, wherein:
the third circuit further comprises a controller for providing a customized gain to each amplifier of the first, second, third and fourth channels and for providing a customized truncation command to each ADC of the first, second, third and fourth channels.

6. The system of claim 5, wherein:
total bit reduction equals m+k, where m represents a number of most significant bits skipped and k represents a number of least significant bits truncated;
each of the channels performs the same total bit reduction;
m and k are variable for each of the channels; and
the ADCs of the first, second, third and fourth channels have the same precision.

7. The system of claim 6, wherein:
m and k for each channel are determined a priori; and
the controller is configured to provide the customized gains and truncation commands based on k and m for each channel.

8. The system of claim 5, wherein:
the ADCs do not all have the same precision;
total bit reduction for the i^{th} channel is N-pᵢ, where i={1,2,3,4}, N is a number of bits used to represent the i^{th} analog output signal, and pᵢ is precision of the ADC of the i^{th} channel;
N−pᵢ=mᵢ+kᵢ, where mᵢ is a number of most significant bits skipped by the i^{th} channel and kᵢ is a number of least significant bits truncated by the i^{th} channel; and
mᵢ and kᵢ are variable for each channel.

9. The system of claim 8, wherein:
mᵢ and kᵢ are determined a priori; and
the controller is configured to provide the customized gains and truncation commands based on kᵢ and mᵢ.

10. The system of claim 5, wherein:
the controller is configured to adjust the customized gains of the amplifiers in real time; and
adjusting the customized gain of each amplifier comprises:
taking a sum of a second most significant bit over a number of A/D conversions;
reducing the gain if the sum indicates that use of full amplifier range is above a threshold; and
increasing the gain if the sum indicates that use of the full amplifier range is below a threshold.

11. The system of claim 1, wherein the first circuit is configured to:
receive a first vector having M integer values and a second vector having M integer values, where integer M>1 and where the first vector includes the first integer value and additional integer values, and the second vector includes the second integer value and additional integer values;
split the first vector into a first coarse value vector and a first fine value vector; and
split the second vector into a second coarse value vector and a second fine value vector;
wherein the second circuit is configured to generate the first analog output signal as a dot product of the first and second coarse value vectors, the second analog output signal as a dot product of the first coarse value vector and the second fine value vector, the third analog output signal as a dot product of the first fine value vector and the second coarse value vector, and the fourth analog output signal as a dot product of the first and second fine value vectors; and
wherein the third circuit is configured to perform the customized MSB skipping and LSB truncation on the analog output signals after M accumulations have been completed.

12. The system of claim 11, wherein after the M accumulations have been completed, the conversion is performed at less than full precision, where full precision is defined as 2N+log 2(M), where N is bit width of the integer values.

13. The system of claim 11, wherein:
the integer values of first and second vectors are N bits wide;
the integer values of the coarse value vectors are K bits wide; and
the integer values of the fine value vectors are Y bits wide, where Y<N, K<N, and N, K and Y are integers.

14. The system of claim 13, wherein:
N=8, K=4 and Y=4;
each fine value has a rounded LSB; and
the system further comprises a fourth circuit configured to produce a reconstructed digital output signal as
$${Y}_{R} = {2}^{8} Z 0 + {2}^{5} Z 1 + {2}^{5} Z 2 + {2}^{2} Z 3$$
where Y_{R} is the reconstructed digital output signal, and Z0, Z1, Z2 and Z3 are the first, second, third and fourth digital signals, respectively.

15. The system of claim 13, wherein:
N=8, K=4 and Y=5; and
the system further comprises a fourth circuit configured to produce a reconstructed digital output signal as
$${Y}_{R} = {2}^{8} Z 0 + {2}^{4} Z 1 + {2}^{4} Z 2 + Z 3$$
where Y_{R} is the reconstructed digital output signal, and Z0, Z1, Z2 and Z3 are the first, second, third and fourth digital signals, respectively.

16. A computer-implemented method of multiplying first and second input vectors, each of the vectors having M integer values, the method comprising:
splitting the first input vector into a first coarse value vector and a first fine value vector;
splitting the second input vector into a second coarse value vector and a second fine value vector;
using a plurality of analog multiply and accumulate (MAC) units to generate a first analog signal representing a dot product of the first and second coarse value vectors, a second analog signal representing a dot product of the first coarse value vector and the second fine value vector, a third analog signal representing a dot product of the first fine value vector and the second coarse value vector, and a fourth analog signal representing a dot product of the first and second fine value vectors; and
performing amplification and analog-to-digital (A/D) conversion on each of the first, second, third and fourth analog signals such each amplification and A/D conversion skips its own number of most significant bits and truncates its own number of least significant bits.

17. The method of claim 16, wherein the amplification includes increasing signal amplitude beyond full-scale input range of the A/D conversion.

18. The method of claim 16, further comprising producing a reconstructed digital output signal from first, second, third and fourth digital output signals produced by the A/D conversion, such that the reconstructed digital output signal represents a dot product of the first and second input vectors.

19. A computing device for running a neural network, the device comprising:
a plurality of switched capacitor units configured to perform matrix multiplication on an input vector and a weight vector; and
a digital processor programmed to apply activation functions to outputs of the switched capacitor units;
wherein each switched capacitor unit configured to:
split values of an input vector into first coarse value vectors and first fine value vectors;
split values of a weight vector into second coarse value vectors and second fine value vectors;
perform analog multiply and accumulate (MAC) operations to take a first dot product of the first and second coarse value vectors, a second dot product of the first coarse value vector and the second fine value vector, a third dot product of the first fine value vector and the second coarse value vector, and a fourth dot product of the first and second fine value vectors; and
produce a reconstructed digital signal from the first, second, third and fourth dot products, including performing amplification and analog-to-digital (A/D) conversion on each dot product, such that each amplification and conversion skips its own number of most significant bits and truncates its own number of least significant bits.

20. The computing device of claim 19, wherein each switched capacitor unit includes first, second, third and fourth switched capacitor-based MAC engines configured to produce the first, second, third and fourth dot products, respectively.
